(19) United States
(12) Patent Application Publication
(10) Pub. No.: US 2025/0117529 A1
(43) Pub. Date: Apr. 10, 2025

(54) SYSTEMS AND METHODS FOR ANALYZING AN ARCHITECTURE OF A STRUCTURE

(71) Applicant: Lenovo (Singapore) Pte. Ltd., Singapore (SG)

(72) Inventors: William Holroyd, Morrisville, NC (US); Sergei Rodionov, Morrisville, NC (US); Alfredo Zugasti, Morrisville, NC (US)

(21) Appl. No.: 18/480,923

(22) Filed: Oct. 4, 2023

(51) Int. Cl. G06F 30/13; G02B 27/01; G06T 7/70; G06T 17/00

(52) U.S. Cl. CPC G06F 30/13; G02B 27/017; G06T 7/70; G06T 17/00; G02B 2027/0178

(57) ABSTRACT

A system and a method are configured to determine aspects of a structure. The system and method include an XR architectural analysis device including one or more sensors configured to detect the aspects of the structure. The XR architectural analysis device is configured to output a signal including data regarding the aspects of the structure. A control unit is in communication with the XR architectural analysis device. The control unit is configured to receive the signal, and determine the aspects of the structure based on the data.

### BACKGROUND

Embodiments of the present disclosure generally relate to systems and methods for analyzing an architecture of a structure, such as a room within a residential or commercial building.

Various buildings include features that are inspected during and after construction. For example, residential and commercial buildings include rooms that are inspected to determine certain components within walls, floors, ceilings, and the like.

Certain hand tools can be used to measure objects, find studs, structural supports, and/or the like within the structures. Most methods for analyzing rooms seek the least cost, given the cost of most construction projects. Smartphone applications can be used to help estimate room dimensions using a camera of the smartphone. As another example, a magnetometer of a smartphone can be used to help locate wall studs. As another example, certain peripherals of smartphones can be used to provide information regarding sub-surface locations of architectural elements.

As another example, light detection and ranging (LIDAR) systems can mount to a top of a tripod and provide specific details of a room. However, the LIDAR systems are relatively expensive, bulky, and may operate over a relatively long period of time.

### SUMMARY

A need exists for a system and a method for efficiently and effectively analyzing a structure, such as a room within a building. With that need in mind, certain examples of the present disclosure provide a system configured to determine aspects of a structure. The system includes an architectural analysis device including one or more sensors configured to detect the aspects of the structure. The architectural analysis device is configured to output a signal including data regarding the aspects of the structure. A control unit is in communication with the architectural analysis device. The control unit is configured to receive the signal, and determine the aspects of the structure based on the data.

The system can also include a user interface including a display. The control unit is configured to show the aspects of the structure on the display.

The architectural analysis device can be separate and distinct from the control unit. Optionally, the architectural analysis device can include the control unit.

In at least one example, the architectural analysis device is an XR device. The XR device is one of a mixed reality device, a virtual reality device, or an augmented reality device.

In at least one example, the control unit is further configured to generate a three-dimensional (3D) model of the structure from the data.

In at least one example, the control unit is further configured to determine locations of one or more features of the structure from distances between components as detected by the architectural analysis device. For example, the one or more features include studs, and the components include one or both of switches or outlets.

The one or more sensors can include an acoustic sensor, such as a microphone array.

In at least one example, the control unit is further configured to identify load bearing walls from the data.

The control unit can be an artificial intelligence or machine learning system.

The architectural analysis device can include a headset, glasses, an eyepiece, a harness, a wand, a stand, and/or a mobile sub-system.

Certain examples of the present disclosure provide a method for determining aspects of a structure. The method includes detecting, by an architectural analysis device including one or more sensors, the aspects of the structure; outputting, by the architectural analysis device, a signal including data regarding the aspects of the structure; receiving, by a control unit in communication with the architectural analysis device, the signal; and determining, by the control unit, the aspects of the structure based on the data.

### BRIEF DESCRIPTION OF THE DRAWINGS

FIG. 1 illustrates a schematic block diagram of a system for analyzing a structure, according to an example of the present disclosure.

FIG. 2 illustrates a simplified block diagram of architectural analysis devices, according to an example of the present disclosure.

FIG. 3 illustrates a simplified top plan view of a structure, according to an example of the present disclosure.

FIG. 4 illustrates a simplified top plan view of a structure, according to an example of the present disclosure.

FIG. 5 illustrates a simplified front view of a wall within a structure, according to an example of the present disclosure.

### DETAILED DESCRIPTION

It will be readily understood that the components of the embodiments as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, appearances of the phrases “in one embodiment,” “in an embodiment” or the like in various places throughout this specification are not necessarily all referring to the same embodiment.

Furthermore, the described features, structures or characteristics may be combined in any suitable manner in one or more embodiments. In the following description, numerous specific details are provided to give a thorough understanding of the various embodiments. One skilled in the relevant art will recognize, however, that the various embodiments can be practiced without one or more of the specific details, or with other methods, components, materials, etc. In other instances, well-known structures, materials, or operations are not shown or described in detail to avoid obfuscation. The following description is intended only by way of example, and simply illustrates certain example embodiments.

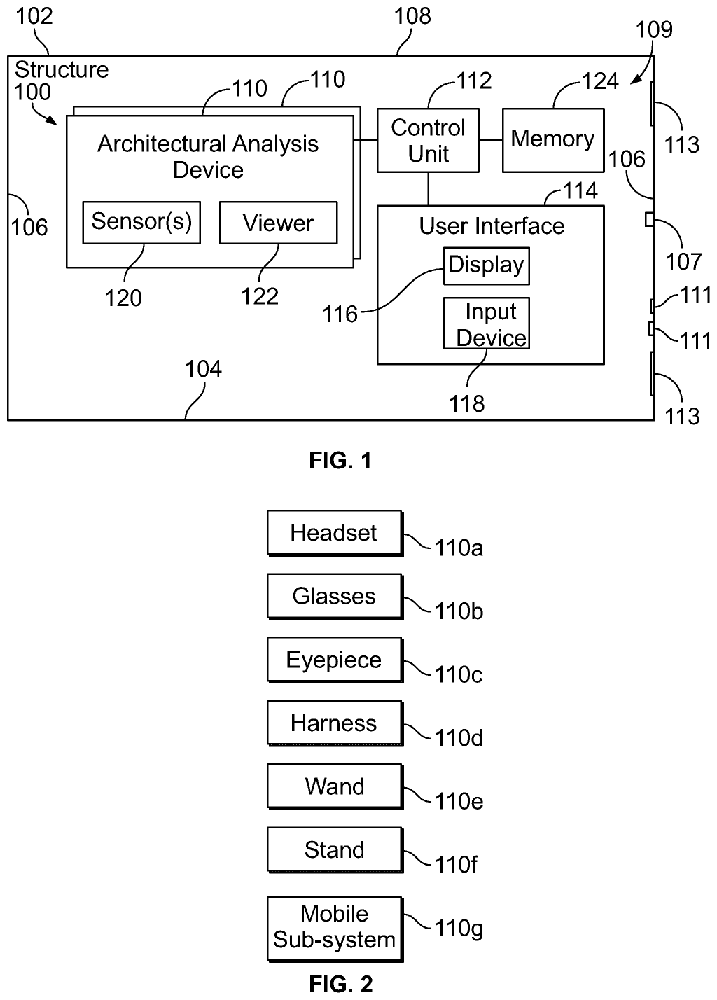

FIG. 1 illustrates a schematic block diagram of a system 100 for analyzing a structure 102, according to an example of the present disclosure. In at least one example, the structure 102 is a room within a building, such as a residential or commercial building. The structure 102 includes a floor 104, one or more walls 106, and a ceiling 108. An interior space 109 is defined between the floor 104, the wall(s) 106, and the ceiling 108. Optionally, the structure 102 may not include a ceiling, for example. The structure 102 may or may not be enclosed.

The system 100 includes an architectural analysis device 110 in communication with a control unit 112, such as through one or more wired or wireless connections. The control unit 112 is coupled to a memory 124, such as through one or more wired or wireless connections. The control unit 112 can be separate and distinct from the memory 124. Optionally, the control unit 112 includes the memory 124.

The control unit 112 is also in communication with a user interface 114, such as through one or more wired or wireless connections. The user interface 114 includes a display 116 and an input device 118. For example, the display 116 is an electronic monitor, television, and/or the like, and the input device 118 includes one or more of a keyboard, a mouse, a stylus, and/or the like. In at least one example, the display 116 and the input device 118 are integrated as a touchscreen interface. In at least one example, the user interface 114 is a computer workstation. As another example, the user interface 114 is a handheld device, such as a smartphone, smart tablet, or the like.

As shown, the architectural analysis device 110 can be separate and distinct from the control unit 112 and the user interface 114. In at least one example, the architectural analysis device 110, the control unit 112, and the user interface 114 are within interior space 109 of the structure 102. As another example, the control unit 112 and the user interface 114 can be outside of the interior space 109, such as within another room. In at least one other example, the architectural analysis device 110 includes the control unit 112 and the user interface 114. For example, a housing, such as a workstation, a handheld device, a headset, a harness, and/or the like can include the architectural analysis device 110, the control unit 112, and the user interface 114.

In at least one example, the architectural analysis device 110 is an XR device. The XR device can be a mixed reality device, a virtual reality device, or an augmented reality device. The XR device has special awareness of surroundings, and one or more sensors configured to approximate distance, angles, and measurement of points within a field of vision. The XR device is further configured to record data, and/or view objects within the structure 102.

In at least one example, the architectural analysis device 110 is an XR device that includes one or more sensors 120, and a viewer 122. The sensor(s) 120 can include one or more of an acoustic sensor (such as one or more ultrasonic detectors, one or more microphones, and/or the like), an optical sensor (such as a camera, an infrared detector, a LIDAR sensor, one or more lasers, and/or the like), a pressure sensor, and/or the like. The viewer 122 can be separate and distinct from the sensor(s) 120. The viewer 122 can be a video camera, an infrared camera, and/or the like. Optionally, the viewer 122 can be a sensor 120.

The architectural analysis device 110 can be operated by an individual to detect various features of the structure 102. As an example, the architectural analysis device 110 can include a headset worn by an individual within the structure 102. Optionally, the architectural analysis device 110 can be a handheld device. As another example, the architectural analysis device 110 can be a stationary system, such as mounted on a stand, for example, a tripod.

In operation, the architectural analysis device 110 is manipulated, moved, and/or the like to view various features within the structure 102, such as the walls 106, the floor 104, and/or the ceiling 108. The viewer 122 is configured to view and output image data of the various features. As an example, if the architectural analysis device 110 is viewing a wall 106 with a light switch 107 and outlets 111, the one or more sensors 120 are able to measure distances between the various features. The control unit 112 receives signals from the sensors 120 including the distance data. In response, the control unit 112 then determines (such as via deduction) which side of the light switch 107 and/or the outlets 111 where studs 113 in the wall 106 are located. For example, the memory 124 stores building code data that includes information regarding locations for various components in relation to other components. The control unit 112 retrieves the building code data from the memory 124. As an example, a building code may dictate that switches and outlets are to be affixed to a stud. Such information is stored in the memory 124 within the building code data. Some types of construction are either “16 on center” or “24 on center” (in relation to inches between each stud, and measured from the middle of the stud). Thus, when the architectural analysis device 110 acquires images of the switches 107 and the outlets 111 on the wall 106, the architectural analysis device 110 determines the locations of the studs 113, such as through the building code data within the memory 124.

In at least one example, the architectural analysis device 110 is an XR device that acquires images of various features of the structure 102. After the architectural analysis device 110 acquires the images of the various features within the structure 102. the control unit 112 recognizes the features through data stored in the memory 124, and the generated three-dimensional (3D) models of the structure 102. In this manner, the control unit 112 can generate a virtual, 3D doll house that includes one or more structures, such as the structure 102.

In response to generating a 3D model of the structure 102, the control unit 112 outputs a model signal to the user interface 114. The model signal includes the data regarding the 3D model. The control unit 112 can then show the 3D model on the display 116 via the model signal. The model signal can also include information regarding distances between features, locations of the features, and/or the like, which can also be shown on the display in the form of graphics, text, and/or the like.

In at least one example, a plurality of architectural analysis devices 110, such as multiple XR devices, can be used to provide information regarding the structure 102. Information from the architectural analysis devices 110 can be received by the control unit 112 and integrated to provide a unified view of the various features within the structure 102, which can then be shown on the display 116. For example, two different architectural analysis devices 110 can be operated on opposite sides of any given wall. Information acquired from the different architectural analysis devices 110 can be received and analyzed by the control unit 112 to generate 3D model with increased accuracy.

As noted, the sensor(S) 120 can include acoustic sensors, such as a microphone array. The microphone array can be operated to help locate components hidden in a floor 104, wall 106, or ceiling 108, such as pipes used for running coolant for air conditioning, water, sewage, and drainage through use of directional sound location. As an example, a toilet can be flushed, and the microphone array can detect audio signals to determine where water is flowing within the walls. The control unit 112 receives such signals from the microphone array, and can then determine a location of pipes within the floor 104, the wall(s) 106, and/or the ceiling 108. As another example, an air conditioner can be activated, and the microphone array detects audio signals where a coolant line runs, which can then be determined by the control unit 112.

The 3D model generated by the control unit 112 can include information regarding well known and shared building standards. In this manner, the 3D model can be analyzed to identify how a structure may be built.

The control unit 112 can further identify load bearing walls from data stored in the memory 124. Such data includes material lengths, locations of walls, and/or features within the structure 102. The control unit 112 can also analyze the data stored within the memory 124 to identify stud spacing through placement of outlets, switches, or features that highlight joists and nail pops. Further, the control unit 112 can analyze the data stored in the memory 124 to determine which direction flooring or ceiling support beams may travel, and/or plumbing and electrical features within the floor 104, walls 106, and/or ceiling 108.

In at least one example, the 3D model of the structure 102 generated by the control unit 112 can be mapped with an image acquired by the viewer 122 (such as within an XR headset or XR enabled device) to provide a physical view with properties that can be shown in relation to the virtual 3D model. The control unit 112 can further provide indicia (such as graphics, texts, or the like) onto the 3D model and/or image provide information regarding a design of the structure 102.

In at least one example, the 3D model generated by the control unit 112 can be augmented by one or more additional devices, such as a snorkel camera/camera snake shoved into smaller places the architectural analysis device 110 may not fit. In at least one example, the control unit 112 can generate and provide a video stream to a display of the architectural analysis device (such as within an XR headset) and/or the display 116 to show in-wall locations of pipes, wires, or other architectural details like structural brackets.

As described herein, examples of the present disclosure provide the system 100 configured to determine aspects of the structure 102. The system includes the architectural analysis device 110 including one or more sensors 120 configured to detect the aspects of the structure 102. The architectural analysis device 110 is configured to output a signal including data regarding the aspects of the structure 102. The control unit 112 is in communication with the architectural analysis device 110. The control unit 112 is configured to receive the signal, and determine the aspects of the structure 102 through analysis of the data. The aspects can include dimensions of the room (such as length, width, height), sizes and shapes of the floor 104, walls 106, and ceiling 108, locations of various features within portions of the structure 102 (such as switches 107, outlets 111, studs 113), and/or the like.

As used herein, the term “control unit,” “central processing unit,” “CPU,” “computer,” or the like may include any processor-based or microprocessor-based system including systems using microcontrollers, reduced instruction set computers (RISC), application specific integrated circuits (ASICs), logic circuits, and any other circuit or processor including hardware, software, or a combination thereof capable of executing the functions described herein. Such are exemplary only, and are thus not intended to limit in any way the definition and/or meaning of such terms. For example, the control unit 112 may be or include one or more processors that are configured to control operation, as described herein.

The control unit 112 is configured to execute a set of instructions that are stored in one or more data storage units or elements (such as one or more memories), in order to process data. For example, the control unit 112 may include or be coupled to one or more memories. The data storage units may also store data or other information as desired or needed. The data storage units may be in the form of an information source or a physical memory element within a processing machine.

The set of instructions may include various commands that instruct the control unit 112 as a processing machine to perform specific operations such as the methods and processes of the various embodiments of the subject matter described herein. The set of instructions may be in the form of a software program. The software may be in various forms such as system software or application software. Further, the software may be in the form of a collection of separate programs, a program subset within a larger program, or a portion of a program. The software may also include modular programming in the form of object-oriented programming. The processing of input data by the processing machine may be in response to user commands, or in response to results of previous processing, or in response to a request made by another processing machine.

The diagrams of embodiments herein may illustrate one or more control or processing units, such as the control unit 112. It is to be understood that the processing or control units may represent circuits, circuitry, or portions thereof that may be implemented as hardware with associated instructions (e.g., software stored on a tangible and non-transitory computer readable storage medium, such as a computer hard drive, ROM, RAM, or the like) that perform the operations described herein. The hardware may include state machine circuitry hardwired to perform the functions described herein. Optionally, the hardware may include electronic circuits that include and/or are connected to one or more logic-based devices, such as microprocessors, processors, controllers, or the like. Optionally, the control unit 112 may represent processing circuitry such as one or more of a field programmable gate array (FPGA), application specific integrated circuit (ASIC), microprocessor(s), and/or the like. The circuits in various embodiments may be configured to execute one or more algorithms to perform functions described herein. The one or more algorithms may include aspects of embodiments disclosed herein, whether or not expressly identified in a flowchart or a method.

As used herein, the terms “software” and “firmware” are interchangeable, and include any computer program stored in a data storage unit (for example, one or more memories) for execution by a computer, including RAM memory, ROM memory, EPROM memory, EEPROM memory, and non-volatile RAM (NVRAM) memory. The above data storage unit types are exemplary only, and are thus not limiting as to the types of memory usable for storage of a computer program.

In at least one example, all or part of the systems and methods described herein may be or otherwise include an artificial intelligence (AI) or machine-learning system that can automatically perform the operations of the methods also described herein. For example, the control unit 112 can be an artificial intelligence or machine learning system. These types of systems may be trained from outside information and/or self-trained to repeatedly improve information shown on the display 116, for example. The control unit 112 can determine features and locations of the features within the structure 102 via artificial intelligence and/or machine learning. Over time, these systems can improve by matching records with increasing accuracy and speed, thereby significantly reducing the likelihood of any potential errors. The AI or machine-learning systems described herein may include technologies enabled by adaptive predictive power and that exhibit at least some degree of autonomous learning to automate and/or enhance pattern detection (for example, recognizing irregularities or regularities in data), customization (for example, generating or modifying rules to optimize record matching), or the like. The systems may be trained and re-trained using feedback from one or more prior analyses of samples and/or data. Based on this feedback, the systems may be trained by adjusting one or more parameters, weights, rules, criteria, or the like, used in the analysis of the same or other samples. This process can be performed using generated data instead of training data, and may be repeated many times to repeatedly improve the correlation of commands. The training of the record matching system minimizes false positives and/or false negatives by performing an iterative training algorithm, in which the systems are retrained with an updated set of data and based on the feedback examined prior to the most recent training of the systems. This provides a robust analysis model that can better determine features, locations of features, distances between features, and/or the like.

FIG. 2 illustrates a simplified block diagram of architectural analysis devices, according to an example of the present disclosure. A headset 110a is an example of an architectural analysis device. The headset 110a is configured to be worn by an individual. In at least one example, the headset 110a is an XR headset.

Glasses 110b are an example of an architectural analysis device. The glasses 110b are configured to be worn by an individual. In at least one example, the glasses 110b are XR glasses.

An eyepiece 110c is an example of an architectural analysis device. The eyepiece 110c is configured to be worn by an individual. In at least one example, the eyepiece 110c is an XR eyepiece.

A harness 110d is an example of an architectural analysis device. The harness 110d is configured to be worn by an individual. In at least one example, the harness 110d is an XR harness.

A wand 110e is an example of an architectural analysis device. The wand 110e is configured to be held and manipulated by an individual. In at least one example, the wand 110e is an XR wand.

A stand 110f is an example of an architectural analysis device. The stand 110f is configured to be placed on a structure, and supported on a floor. The stand 110f can be a tripod, for example. The stand 110f can include one or more actuators configured to automatically move a viewer, sensors, and/or the like. In at least one example, the stand 110f is an XR stand.

A mobile sub-system 110g is an example of an architectural analysis device. The mobile sub-system 110g can include a conveyance, such as one or more wheels, tracks, and/or the like, a navigation sub-system, and/or the like configured to allow the mobile sub-system 110g to automatically move throughout a structure. The mobile sub-system 110g further includes sensor(s) and a viewer, as described herein. In at least one example, the mobile sub-system 110g is a robot. In at least one example, the mobile sub-system 110g is an XR mobile sub-system.

In at least one example, an architectural analysis device includes one or more of the headset 110a, the glasses 110b, the eyepiece 110c, the harness 110d, the wand 110e, the stand 110f, and/or the mobile sub-system 110g.

FIG. 2 shows examples of the architectural analysis devices. The examples shown in FIG. 2 are non-limiting. Other types of architectural analysis devices can be used.

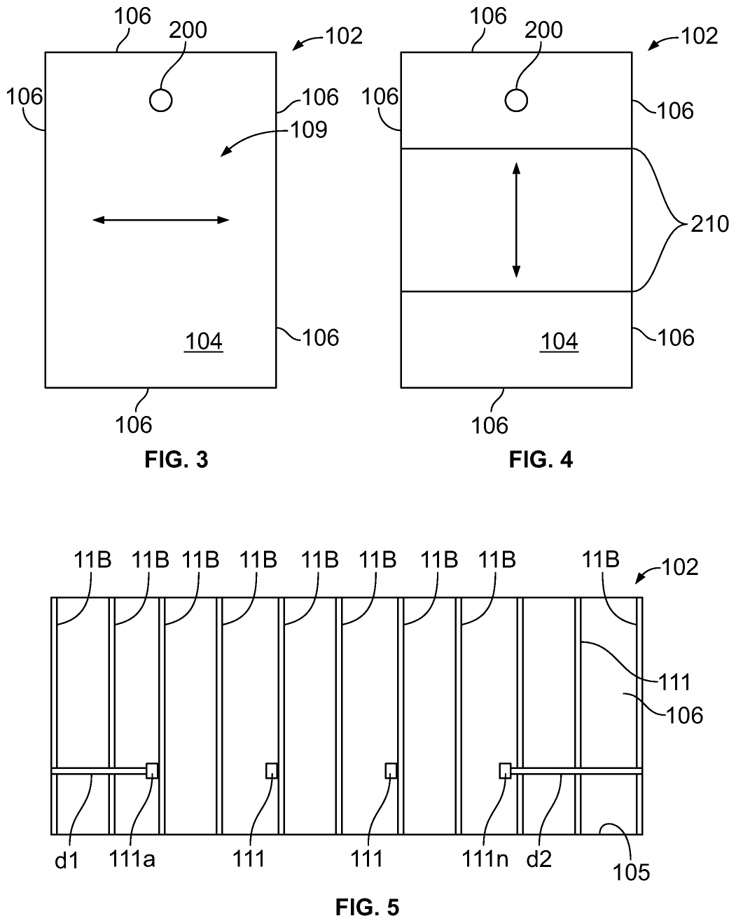

FIG. 3 illustrates a simplified top plan view of a structure 102, according to an example of the present disclosure. Referring to FIGS. 1 and 2, an individual 200 within the interior space 109 of the structure 102 has the architectural analysis device 110. For example, the individual 200 can be wearing the architectural analysis device 110, which can be an XR headset.

The individual 200 moves throughout the enclosed space 109 so that the architectural analysis device 110 acquires data regarding the structure 102, such as through the sensor(s) 120 and the viewer 122. In this manner, the data acquired by the architectural analysis device 110 is received by the control unit 112, which then determines the dimensions of the structure 102 through the received data. By retrieving stored data in the memory 124 regarding the structure 102 (such as building code data, architectural data, and/or the like), the control unit 112 can then determine directions of material within various structures (such as the floor 104, the walls 106, and/or the ceiling 108) to determine locations of load bearing walls.

As an example, data stored in the memory 124 may indicate that a maximum length of wood materials in horizontal layouts is about 16-20 feet, depending on width and depth of the lumber. Based on this materials knowledge, the control unit 112 is able to determine that one or more of the walls 106 are load bearing, as the beams are not long enough to span a 40 feet room without extreme lengths of wood materials or more extensive materials such as steel if a beam or support is required every 16 inches, as indicated in the stored data. A standard distance between supports in floors, walls, and ceilings may be 16 inches, which is referred to as “16 on center.” As another example, some buildings may utilize “24 on center” for walls.

FIG. 4 illustrates a simplified top plan view of a structure 102, according to an example of the present disclosure. Referring to FIGS. 1 and 4, in at least one example, in the event that the structure 102 exhibits support beams 210 in the ceiling 108 going from left to right (as detected by the architectural analysis device 110 operated by the individual 200), the control unit 112 retrieves building code and/or architectural data within the memory 124, and thereby determines that all four walls 106 are load bearing, as the left and right walls will support the horizontal beams, as well as the end of the floor support joists for the top and bottom areas of the ceiling.

FIG. 5 illustrates a simplified front view of a wall 106 within a structure 102, according to an example of the present disclosure. Referring to FIGS. 1 and 5, the architectural analysis device 110 acquires data indicating that that the wall 106 includes electrical outlets 111 spaced every 6 feet above a floor line 105. Based on data stored in the memory 124, the control unit 112 determines a presence of a stud 113 behind the wall 106. Based on the data stored within the memory 124, the control unit 112 further determines that, absent some other structural element being present, a plain 40 feet×16 feet sized room as shown has studs 113 located where indicated, such as based on a “16 on center” or a “24 on center” rule (as stored in the memory 124). One of the sensors 120 can be an infrared laser array that is used to detect imperfections in a surface of the wall 106 to detect where sheets of drywall may be seamed together (edges are nailed to studs in the wall), and/or provide other visual indicators such as barely noticeable “nail pops” to identify stud locations.

In at least one example, the architectural analysis device 110, via one or more sensors 120 detects a distance d1 of 29 inches from a first side of the structure to a first outlet 111a, and a distance d2 of 35 inches from a second side of the room to a final outlet 111n. Based on data stored in the memory 124, the control unit 112 determines that the structure 102 uses a “16 on center” stud configuration, and is therefore able to determine the locations of each of the studs 113.

Referring to FIGS. 1-5, the system 100 can be used to determine plumb, square, or level indications within the structure 102. For example, the sensors 120 can include an optical sensor, such as infrared laser array, and a gyro sensor, which can help engineers understand issues with the building where sagging, slope, and settling may have developed over time, or was introduced in prior construction. This information can be used to understand if floors need to be inspected for termites, rot, or improper floor deflection calculations (for example, wrong width or height beams were used for room dimensions), and help identify changes that may be needed to rectify such issues. In some locations, the degree of slope of a floor is acceptable within certain thresholds, wherein others may require correction if that part of the building is being remodeled or worked on to pass building inspections.

The system 100 can be used to augment wiring diagrams from electrical outlet and switch placements, and proximity to water sources. Electrical code may indicate a type of circuit for outlets 111 if within certain distance of water sources. Outlets within a kitchen or bathroom for example are typically part of a circuit that contains a GFI/GFCI circuit in the event of water causing short circuits. Such information can use color indicators for normal circuits in relation to GFI/GFCI circuits by highlighting and/or outlining the outlets and estimated line locations rendered on the wall where wires are likely located.

The system 100 can also be used to provide material calculation estimates from 3D models generated by the control unit 112. Dimensions can be used to calculate cost estimates depending on the type of work being performed (such as areas of walls for paint or wallpaper, amount of drywall in restoration efforts, and square footage of flooring area for carpet or hardwood floors). Dimensions can also be used to calculate HVAC airflow parameters for air exchange requirements for air conditioning systems, which may be required during installation, replacement, and system verification if installations were suspected to be oversized or undersized. The calculation accounts for the dimensions of the room, and also the number of windows, the type of windows, and the thickness of the walls, which can help define an overall weight of the units, ductwork sizing, and possibly zones.

The system 100 can also be used to covert the 3D model(s) to blueprints. Existing home structures may not have blueprints. They are either not provided to the home owner, or get lost or thrown away at some point in time. The control unit 112 can generate the 3D model, as described herein, to assist in generating blueprints for modification by architects or general contractors to provide information for remodeling, addition, or restoration efforts.

As described herein, examples of the present disclosure provide systems and methods that generate 3D models of structures (for example, doll house models) having contextual clues gained from visual indicators and measurements to identify structural details. The control unit 112 can augment the 3D model with in-wall, in-floor, and in-ceiling details and metadata. The 3D model can be used to provide architectural diagrams and blueprints, material volume/area estimates, and type of materials used to build a structure. The control unit 112 can analyze building standard or code data along with the generated 3D model of the structure 102 to visually indicate how the structure 102 is most likely constructed, wired, and plumbed without destructive changes to the structure 102. Data stored within the memory 124 can include materials information to identify products used in construction.

Further, the disclosure comprises embodiments according to the following clauses:

Clause 1: A system configured to determine aspects of a structure, the system comprising:
an architectural analysis device including one or more sensors configured to detect the aspects of the structure, wherein the architectural analysis device is configured to output a signal including data regarding the aspects of the structure; and
a control unit in communication with the architectural analysis device, wherein the control unit is configured to receive the signal, and determine the aspects of the structure based on the data.

Clause 2. The system of Clause 1, further comprising a user interface including a display, wherein the control unit is configured to show the aspects of the structure on the display.

Clause 3. The system of Clauses 1 or 2, wherein the architectural analysis device is separate and distinct from the control unit.

Clause 4. The system of any of Clauses 1-3, wherein the architectural analysis device includes the control unit.

Clause 5. The system of any of Clauses 1-4, wherein the architectural analysis device is an XR device, and wherein the XR device is one of a mixed reality device, a virtual reality device, or an augmented reality device.

Clause 6. The system of any of Clauses 1-5, wherein the control unit is further configured to generate a three-dimensional (3D) model of the structure from the data.

Clause 7. The system of any of Clauses 1-6, wherein the control unit is further configured to determine locations of one or more features of the structure from distances between components as detected by the architectural analysis device.

Clause 8. The system of Clause 7, wherein the one or more features comprise studs, and wherein the components comprise one or both of switches or outlets.

Clause 9. The system of any of clauses 1-8, wherein the one or more sensors comprise a microphone array.

Clause 10. The system of any of Clauses 1-9, wherein the control unit is further configured to identify load bearing walls from the data.

Clause 11. The system of any of Clauses 1-10, wherein the control unit is an artificial intelligence or machine learning system.

Clause 12. The system of any of Clauses 1-11, wherein the architectural analysis device comprises one or more a headset, glasses, an eyepiece, a harness, a wand, a stand, or a mobile sub-system.

Clause 13. A method for determining aspects of a structure, the method comprising:
detecting, by an architectural analysis device including one or more sensors, the aspects of the structure;
outputting, by the architectural analysis device, a signal including data regarding the aspects of the structure;
receiving, by a control unit in communication with the architectural analysis device, the signal; and
determining, by the control unit, the aspects of the structure based on the data.

Clause 14. The method of Clause 13, further comprising showing, by the control unit, the aspects of the structure on a display of a user interface.

Clause 15. The method of Clauses 13 or 14, wherein the architectural analysis device is separate and distinct from the control unit.

Clause 16. The method of any of Clauses 13-15, wherein the architectural analysis device includes the control unit.

Clause 17. The method of any of Clauses 13-16, wherein the architectural analysis device is an XR device, and wherein the XR device is one of a mixed reality device, a virtual reality device, or an augmented reality device.

Clause 18. The method of any of Clauses 13-17, further comprising generating, by the control unit, a three-dimensional (3D) model of the structure from the data.

Clause 19. The method of any of Clauses 13-18, wherein said determining comprises determining locations of one or more features of the structure from distances between components as detected by the architectural analysis device.

Clause 20. The method of Clause 19, wherein the one or more features comprise studs, and wherein the components comprise one or both of switches or outlets.

As described herein, examples of the present disclosure provide systems and methods for efficiently and effectively analyzing a structure, such as a room within a building.

While various spatial and directional terms, such as top, bottom, lower, mid, lateral, horizontal, vertical, front and the like can be used to describe embodiments of the present disclosure, it is understood that such terms are merely used with respect to the orientations shown in the drawings. The orientations can be inverted, rotated, or otherwise changed, such that an upper portion is a lower portion, and vice versa, horizontal becomes vertical, and the like.

As used herein, a structure, limitation, or element that is “configured to” perform a task or operation is particularly structurally formed, constructed, or adapted in a manner corresponding to the task or operation. For purposes of clarity and the avoidance of doubt, an object that is merely capable of being modified to perform the task or operation is not “configured to” perform the task or operation as used herein.

It is to be understood that the above description is intended to be illustrative, and not restrictive. For example, the above-described embodiments (and/or aspects thereof) can be used in combination with each other. In addition, many modifications can be made to adapt a particular situation or material to the teachings of the various embodiments of the disclosure without departing from their scope. While the dimensions and types of materials described herein are intended to define the parameters of the various embodiments of the disclosure, the embodiments are by no means limiting and are exemplary embodiments. Many other embodiments will be apparent to those of skill in the art upon reviewing the above description. The scope of the various embodiments of the disclosure should, therefore, be determined with reference to the appended claims, along with the full scope of equivalents to which such claims are entitled. In the appended claims and the detailed description herein, the terms “including” and “in which” are used as the plain-English equivalents of the respective terms “comprising” and “wherein.” Moreover, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112 (f), unless and until such claim limitations expressly use the phrase “means for” followed by a statement of function void of further structure.

This written description uses examples to disclose the various embodiments of the disclosure, including the best mode, and also to enable any person skilled in the art to practice the various embodiments of the disclosure, including making and using any devices or systems and performing any incorporated methods. The patentable scope of the various embodiments of the disclosure is defined by the claims, and can include other examples that occur to those skilled in the art. Such other examples are intended to be within the scope of the claims if the examples have structural elements that do not differ from the literal language of the claims, or if the examples include equivalent structural elements with insubstantial differences from the literal language of the claims.

What is claimed is:

1. A system configured to determine aspects of a structure, the system comprising:
an architectural analysis device including one or more sensors configured to detect the aspects of the structure, wherein the architectural analysis device is configured to output a signal including data regarding the aspects of the structure; and
a control unit in communication with the architectural analysis device, wherein the control unit is configured to receive the signal, and determine the aspects of the structure based on the data.

2. The system of claim 1, further comprising a user interface including a display, wherein the control unit is configured to show the aspects of the structure on the display.

3. The system of claim 1, wherein the architectural analysis device is separate and distinct from the control unit.

4. The system of claim 1, wherein the architectural analysis device includes the control unit.

5. The system of claim 1, wherein the architectural analysis device is an XR device, and wherein the XR device is one of a mixed reality device, a virtual reality device, or an augmented reality device.

6. The system of claim 1, wherein the control unit is further configured to generate a three-dimensional (3D) model of the structure from the data.

7. The system of claim 1, wherein the control unit is further configured to determine locations of one or more features of the structure from distances between components as detected by the architectural analysis device.

8. The system of claim 7, wherein the one or more features comprise studs, and wherein the components comprise one or both of switches or outlets.

9. The system of claim 1, wherein the one or more sensors comprise a microphone array.

10. The system of claim 1, wherein the control unit is further configured to identify load bearing walls from the data.

11. The system of claim 1, wherein the control unit is an artificial intelligence or machine learning system.

12. The system of claim 1, wherein the architectural analysis device comprises one or more a headset, glasses, an eyepiece, a harness, a wand, a stand, or a mobile sub-system.

13. A method for determining aspects of a structure, the method comprising:
detecting, by an architectural analysis device including one or more sensors, the aspects of the structure;
outputting, by the architectural analysis device, a signal including data regarding the aspects of the structure;
receiving, by a control unit in communication with the architectural analysis device, the signal; and
determining, by the control unit, the aspects of the structure based on the data.

14. The method of claim 13, further comprising showing, by the control unit, the aspects of the structure on a display of a user interface.

15. The method of claim 13, wherein the architectural analysis device is separate and distinct from the control unit.

16. The method of claim 13, wherein the architectural analysis device includes the control unit.

17. The method of claim 13, wherein the architectural analysis device is an XR device, and wherein the XR device is one of a mixed reality device, a virtual reality device, or an augmented reality device.

18. The method of claim 13, further comprising generating, by the control unit, a three-dimensional (3D) model of the structure from the data.

19. The method of claim 13, wherein said determining comprises determining locations of one or more features of the structure from distances between components as detected by the architectural analysis device.

20. The method of claim 19, wherein the one or more features comprise studs, and wherein the components comprise one or both of switches or outlets.
